(19) United States
(12) Patent Application Publication
(10) Pub. No.: US 2013/0335897 A1
(43) Pub. Date: Dec. 19, 2013

(54) ADAPTER HOLDER AND DISPLAY DEVICE PROVIDED WITH ADAPTER HOLDER

(71) Applicants: Yoshihito Mochizuki, Tokyo (JP); Hsi-ming Chen, Tokyo (JP)

(72) Inventors: Yoshihito Mochizuki, Tokyo (JP); Hsi-ming Chen, Tokyo (JP)

(73) Assignee: NEC Display Solutions, Ltd.

(21) Appl. No.: 13/880,028

(22) PCT Filed: Oct. 22, 2010
(86) PCT No.: PCT/JP2010/068735

§ 371 Date: Aug. 21, 2013

(51) Int. Cl. H05K 5/02; H05K 5/00

(52) U.S. Cl. CPC H05K 5/0217; H05K 5/0017
USPC 361/679.01; 248/231.81; 248/219.4

(57) ABSTRACT

An adapter holder includes: a mounting portion that detachably mounts an adapter; and an attaching portion that is provided at an opposite side to the mounting portion and is configured to attach to and detach from a separate member.

### TECHNICAL FIELD

The present invention relates to an adaptor holder that supports various displays such as a liquid crystal display in a raisable/lowerable manner, and a display device that includes the adapter holder.

### BACKGROUND ART

In recent years, as a display device that is provided with a monitor for display purposes of a personal computer or television, a thin-type display device represented by a liquid crystal display or plasma display has become widely popular. Among these display devices, there is one that is supported by a rising and dropping stand that can be raised and lowered. This rising and dropping stand includes a height adjustment mechanism that is capable of adjusting the height position of the display in accordance with the eye height of the observer.

As a display device that includes this kind of rising and dropping stand, there is one in which a rising and dropping stand is attached to a display of for example a personal computer. For example, as the rising and dropping stand in the display device that is disclosed in Patent Document 1, a rising and dropping member is inserted so as to be able to raise and lower in which a guide member is supported by a base portion and is provided with a display. The guide member and the rising and dropping member are both formed having an approximately rectangular cross-section, and a friction mechanism that uses a one-way clutch is provided between both members. It is constituted so that when the rising and dropping member is raised upward manually, a guide member of the friction mechanism moves somewhat upward, thereby weakening the pressing force due to a leaf spring of the one-way clutch, so that the rising and dropping member moves upward with a light force.

Alternatively, as a friction mechanism, by providing a torque limiter in a Conston spring to weaken the winding force of the spring with respect to a friction roller during elevation of the rising and dropping member, rotation of the friction roller is facilitated, and so the rising and dropping member is elevated with a light force.

Also, in the display stand that is disclosed in Patent Document 2, a display is supported by a supporting pipe that can be raised and lowered, and in this supporting pipe, an upper side pipe can be raised and lowered with respect to a lower side pipe, and they are mutually coupled by a bolt. Then, in the state of the bolt being loosened, the vertical position of the display is adjusted, and by retightening the bolt at the desired height adjustment position, the display can be supported with the supporting pipe fixed.

### PRIOR ART DOCUMENTS

### Patent Documents

[Patent Document 1] Japanese Unexamined Patent Application, First Publication No. 2005-300922
[Patent Document 2] Japanese Unexamined Patent Application, First Publication No. 2003-91242

### SUMMARY OF THE INVENTION

### Problem to be Solved by the Invention

In some of the aforementioned display device, an AC adaptor is attached to the power cord, and the AC adaptor converts AC electric current of the alternating current power supply to DC electric current and supplies the DC electric current to the display of the display device, or supplies current to the display device by converting from a high voltage to a low voltage.

Normally, for reasons of separating heat sources, simplification of design, avoiding noise or the like, the AC adaptor is provided midway in the power cord to be away from the display for example, but since it is heavy and bulky it takes up space and gets in the way.

The present invention has been achieved in view of the above circumstances, and has as its object to provide an adaptor holder that can position and hold an adapter at a predetermined position without becoming a hindrance, and a display device that includes the adaptor holder.

### Means for Solving the Problem

An adapter holder according to the present invention includes: a mounting portion that detachably mounts an adapter; and an attaching portion that is provided at an opposite side to the mounting portion and is capable of attaching to and detaching from a separate member.

The adapter holder according to the present invention can hold an adapter in a mounting portion of the adapter holder that is attached by an attaching portion to a separate member, and can hold the adapter in a predetermined position with the adapter holder so that it is out of the way.

Also, in the adapter holder according to the present invention, the attaching portion may include an engaging portion engaging with the separate member; and a pair of action portions formed at an opposite side to the engaging portion via a partition portion and causing the engaging portion to open and close by resilient deformation with the partition portion serving as a fulcrum, and the partition portion and the action portions may constitute the mounting portion.

By pushing the action portions that constitute a portion of the mounting portion of the adapter holder in mutually proximal directions, the engaging portion of the attaching portion is opened up in directions of mutual separation due to resilient deformation, with the partition portion serving as a fulcrum, and it is possible to remove the attaching portion from the separate member. Also, by the engaging portion sandwiching the separate member in the state of the action portions being pushed in the proximal direction, and then releasing the action portions, it is possible for the engaging portion to engage the separate member. Then, it is possible to mount and hold the adapter on the mounting portion that includes the action portions and the partition portion.

Also, the engaging portion preferably includes: a first engaging portion formed in a direction approximately perpendicular to a lengthwise direction of the separate member and engaging an upper surface of the separate member; and second engaging portions provided in the lengthwise direction of the separate member and sandwiching the separate member.

By placing the first engaging portion on the upper surface of the separate member and causing them to engage, the adapter holder can be held in place without causing it to fall even if the weight of the adapter to be mounted is applied, and by causing the second engaging portions to sandwich the separate member, the adapter holder engages the separate member, whereby it is possible to prevent it from shifting in position in the horizontal direction or coming off. Since it is possible to hold the adapter holder in a rotatable manner centered on the separate member, it is possible to select the mounting position of the adapter with respect to the adapter holder and the holding position of both.

Also, it is preferable that a concave curved surface that connects the first engaging portion and the second engaging portions is provided, and a friction pad is attached to the concave curved surface.

In addition to supporting the adapter holder to be rotatable with respect to the separate member that is held on the concave curved surface, by providing the friction pad, it is possible to inhibit rotation of the adapter holder by the frictional force of the friction pad.

Also, an adapter is supported by a bottom part of the mounting portion, and a concave portion through which passes a cord attached to the adapter is provided in the bottom part.

When the adapter is mounted in the adapter holder, in addition to being able to support the adapter with the bottom part of the mounting portion, the cord can be extended downward from the concave portion, and so does not interfere with the mounting.

A display device including an adapter according to the present invention includes: a display at a stand that is supported by a base member, any of the aforementioned adapter holder is attached, and moreover the separate member is the stand.

According to the present invention, it is possible to house and hold an adapter in the mounting portion of an adapter holder that is attached to a stand, so that it does not get in the way.

Also, in the display device according to the present invention, the stand may include a fixed support column, and a rising and dropping support column that is capable of rising and dropping with respect to the fixed support column, a first engaging portion of the adapter holder may engage an upper end of the fixed support column, and second engaging portions may engage a periphery of the fixed support column.

Also, the adapter holder that is capable of housing an adapter is supported on the stand by the first engaging portion and the second engaging portions to be capable of rotating about the stand, there is freedom in being able to select the mounting position and holding position of the adapter, and moreover it does not get in the way.

### Effect of the Invention

As stated above, according to the adapter holder of the present invention and the display device that includes the adapter holder, it is possible to hold the adapter in the mounting portion of the adapter holder that is attached by the attaching portion to a separate member, and the adapter can be held at a predetermined position, and since it is not scattered on a desk or on the floor it does not get in the way.

### BRIEF DESCRIPTION OF THE DRAWINGS

FIG. 1 is a perspective view that separately shows a rising and dropping stand and an adapter holder of a display device according to an exemplary embodiment of the present invention.

FIG. 2 is a perspective view that shows the adapter holder an AC adapter mounted on the rising and dropping stand of the display device shown in FIG. 1.

FIG. 3 is an enlarged view of essential portions of the adapter holder shown in FIG. 2.

FIG. 4A is a perspective view of the adapter holder with a friction pad shown separated.

FIG. 4B is a perspective view of the adapter holder with the friction pad mounted.

FIG. 5 is perspective view of the adapter holder viewed from a mounting frame side.

### EMBODIMENTS FOR CARRYING OUT THE INVENTION

Hereinbelow, an exemplary embodiment of the present invention shall be described with reference to the appended drawings.

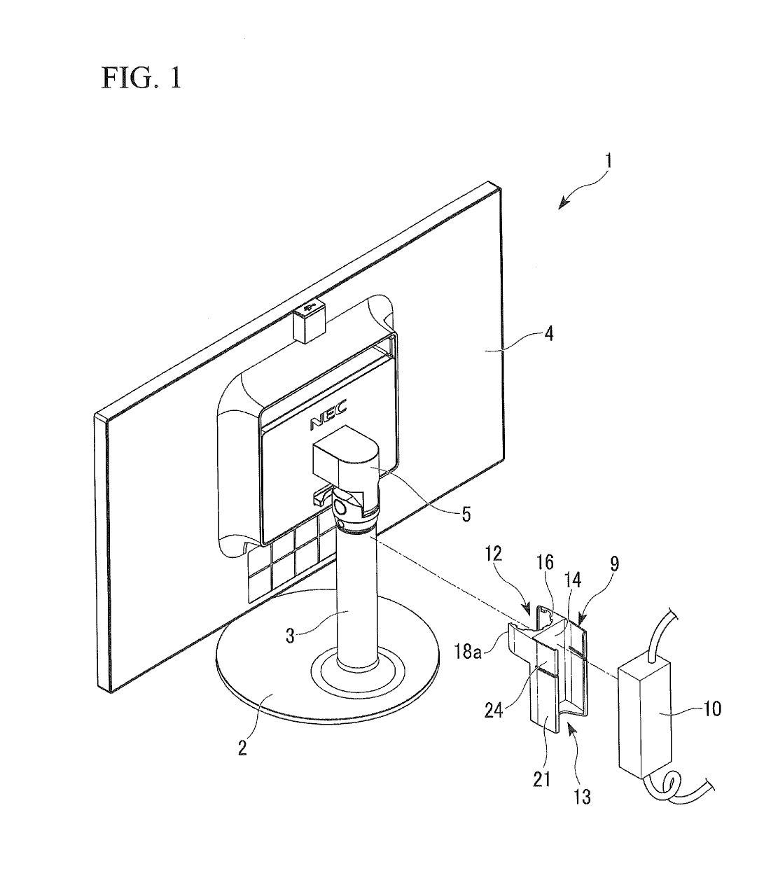

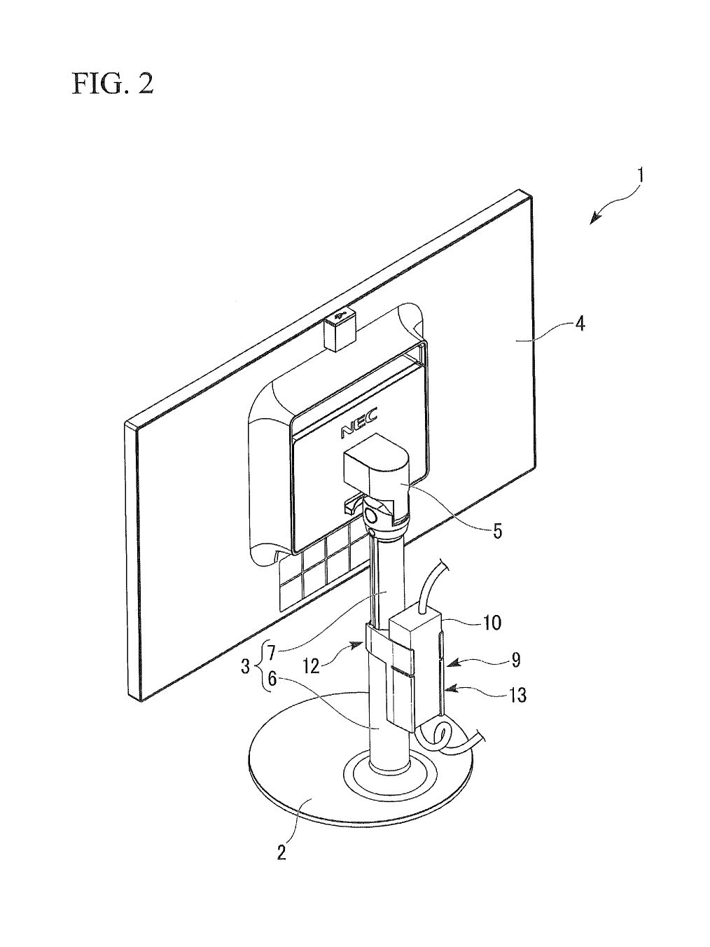

As shown in FIG. 1 and FIG. 2, in a display device 1, a rising and dropping stand 3 that can be raised and lowered is attached to a base-shaped base member 2, and a display 4 such as a liquid-crystal display and a supporting portion 5 therefor are attached to the upper part of the rising and dropping stand 3.

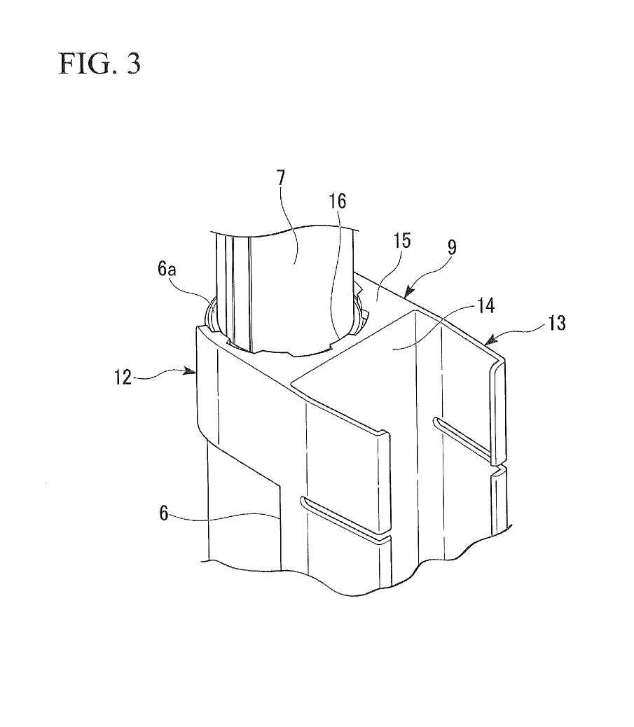

The rising and dropping stand 3 is constituted by a fixed support column 6 that is fixed to the base member 2 and a rising and dropping support column 7 that is capable of rising and dropping with respect to the fixed support column 6, and the fixed support column 6 and the rising and dropping support column 7 are formed for example in a cylindrical shape. As shown in FIG. 3, the rising and dropping support column 7 has a comparatively smaller diameter than the fixed support column 6, and a level difference is formed between the upper end face 6a of the fixed support column 6 and the rising and dropping support column 7.

At the upper end of the rising and dropping support column 7, the supporting portion 5 that fixes the display 4 to the rising and dropping support column 7 is provided in a rotatable manner, and the display 4 is able to rotate integrally with the supporting portion 5.

Then, an adapter holder 9 is removably attached to the fixed support column 6 of the rising and dropping stand 3. The adaptor holder 9 enables mounting of an adapter for supplying electrical current to the display 4. As the adapter, an AC adapter 10 is used which, by inputting an alternating current from an alternating current source, converts it to direct current and outputs it. Alternatively, an AC adapter that only transforms the voltage of an alternating current source may be used.

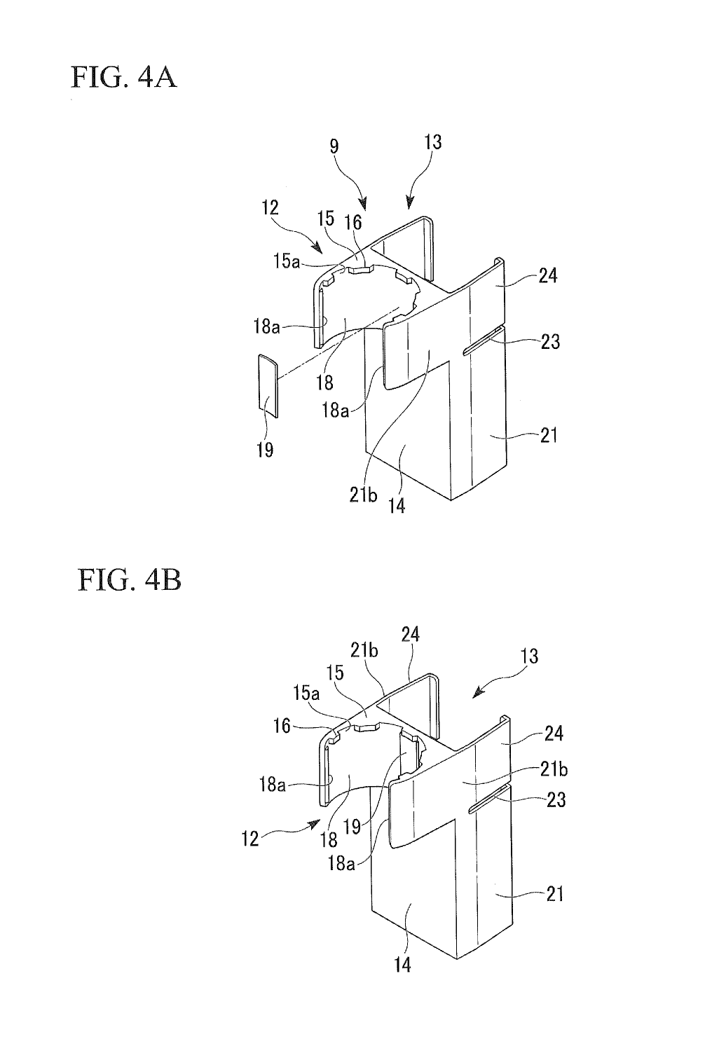

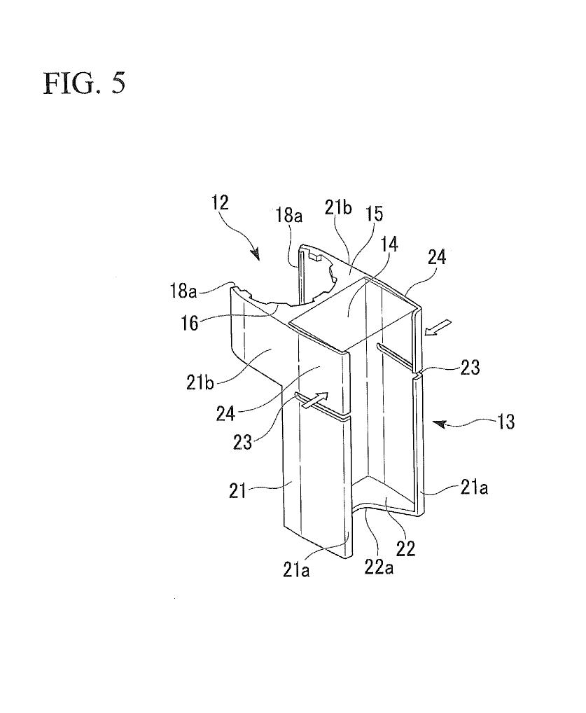

Next, the constitution of the adapter holder 9 shall be described with reference to FIG. 4 and FIG. 5.

In FIG. 4A, FIG. 4B, and FIG. 5, an attaching portion 12 for attachment to the fixed support column 6 of the rising and dropping stand 3 and a mounting frame 13 for mounting and holding the AC adapter 10 sandwich a partition plate 14 and are formed on both sides thereof.

There is funned a supporting plate 15 that extends from the upper end of the partition plate 14 in a plate shape in a direction approximately perpendicular to the partition plate 14, in the attaching portion 12, and there is formed an approximately circular concave portion 15a for engaging the fixed support column 6, in the support plate 15. An inner edge that forms this concave portion 15a extends over a length exceeding 180 degrees, and first engaging portions 16 that include a plurality of teeth spaced apart are formed on the inner periphery of the concave portion 15a (refer to FIG. 3). Note that the reason that the first engaging portions 16 are formed spaced apart is to enable resilient deformation of the concave portion 15a by spreading it apart as described below.

Also, facing downward from the concave portion 15a of the support plate 15, a concave curved surface 18 that forms a portion of the approximately cylindrical inner circumferential surface is formed, and two second engaging portions 18a that has, for example, linear shapes facing each other are formed at both ends in the circumferential direction of the concave curved surface 18. Also, a friction pad 19 with large friction resistance such as rubber or the like for inhibiting rotation of the adapter holder 9 about the fixing column 7 is affixed to the concave curved surface 18.

Also, in the adaptor holder 9, at both end portions in the width direction of the partition plate 14, a pair of mounting plates 21 having an approximate L-shape are formed extending in a region from each second engaging portion 18a of the attaching portion 12, across the partition plate 14, to the mounting frame 13. Latch portions 21a are formed by the end portions of the mounting plates 21 on the opposite side of the second engaging portion 18a being bent or curved to the inside, and the mounting frame 13 forms a U-shape in cross section by the partition plate 14 and the mounting plates 21.

A bottom surface 22 that supports the AC adapter 10 is provided at the lower part of the mounting frame 13, and a concave portion 22a is formed in the bottom surface 22 so as to be able to accept the cord of the AC adapter 10 that extends downward. The upper part of the mounting frame 13 is opened.

Then, in the mounting plates 21 of the mounting frame 13, slits 23 are formed from the latch portion 21a to the vicinity of the partition plate 14 so as to have approximately the same width as the second engaging portions 18a. In the region from the upper end of the mounting plate 21 to the slit 23, the entire plate portion 21b from the second engaging portion 18a to the latch portion 21a is capable of resilient deformation with the partition plate 14 serving as a fulcrum, and the mounting frame 13 region of this plate portion 21b serves as an action portion 24.

When the pair of action portions 24 of the mounting frame 13 are mutually pushed inward with one's fingers, the plate portions 21b undergo resilient deformation, whereby the second engaging portions 18a can open up, and the support plate 15 and the first engaging portions 16 undergo resilient deformation integrally with the plate portions 21b, and thereby can open up.

The display device 1 that includes the adapter holder 9 according to the present exemplary embodiment includes the aforementioned constitution, and next a method for using the adapter holder 9 shall be described.

First, in FIG. 1, an empty adaptor holder 9 is mounted on the fixed support column 6 in the rising and dropping stand 3 of the display device 1. On that purpose, by pushing inward the pair of action portions 24 of the empty adapter holder 9, the pair of plate portions 21b rotate by resilient deformation with the partition plate 14 serving as a fulcrum, and the first engaging portions 16 of the support plate 15 and the second engaging portions 18a of the plate portions 21b rotate so as to open the concave portion 15a and the concave curved surface 18.

Then, the concave portion 15a and the concave curved surface 18 of the attaching portion 12 are made to engage with the fixed support column 6 of the rising and dropping stand 3. At this time, the circumferential surface of the fixed support column 6 is gripped with the second engaging portions 18a, and the support plate 15 is placed on the upper end face 6a of the fixed support column 6, and the rising and dropping support column 7 is inserted into the inside of the concave portion 15a, and the first engaging portions 16 are positioned at the upper end face 6a. Then, by releasing the action portions 24, the resilient deformation of the plate portion 21a reverts to the original state, the circumferential surface of the fixed support column 6 being gripped by clamping with the second engaging portions 18a of the attaching portion 12, and the first engaging portions 16 are made to abut the upper end face 6a of the fixed support column 6.

Thereby, the second engaging portions 18a grip the outer periphery in a manner exceeding the 180 degree range of the fixed support column 6, and as shown in FIG. 3 the first engaging portions 16 are placed on the upper end face 6a of the fixed support column 6 and are hung from it. In this state, the adapter holder 9 is capable of rotating about the rising and dropping stand 3, and the friction pad 19 that is affixed to the concave curved surface 18, by making contact with the outer periphery of the fixed support column 6, inhibits that rotation.

For that reason, in the state of the rising and dropping support column 7 being raised from the fixed support column 6 of the rising and dropping stand 3 as shown in FIG. 2, it is possible to mount the AC adapter 10 in the adapter holder 9 from not only the rear surface but also the side surfaces or the front surface of the display device 1. At the time of mounting, the AC adapter 10 is lowered from the upward opening of the mounting frame 13 of the adapter holder 9 between the partition plate 14 and the action portions 24 and seated on the bottom surface 22, and in this state, the cord that extends downward from the lower surface of the AC adapter 10 extends downward from the concave portion 22.

In this manner, the AC adapter 10 can be mounted in the adapter holder 9 that is attached to the rising and dropping stand 3. For example, in the case of having mounted the AC adapter 10 in the adapter holder 9 from a side surface or front surface of the display device 1, it is possible to rotate the adapter holder 9 to the rear surface of the rising and dropping stand 3 and keep it there. Thereby, when viewing the display device 1 from the front surface side, since the adapter holder 9 and the AC adapter 10 are positioned at the rear surface of the rising and dropping stand 3, they are not conspicuous and so the appearance is good.

As described above, according to the adapter holder 9 of the exemplary embodiment, by undergone resilient deformation by the action portions 24 provided in the pair of mounting plates 21 of the mounting frame 13 with the partition plate 14 serving as a fulcrum, the first engaging portions 16 and the second engaging portions 18a are made to undergo an opening/closing operation, so that the adapter holder 9 can be easily and securely mounted to and removed from the fixed support column 6. Moreover, in the attached state, by causing the first engaging portions 16 to be placed on the upper end face 6a of the fixed support column 6, it is possible to grip so as not to drop by the weight of the AC adapter 10, and by causing the second engaging portions 18a to grip in the state of being engaged on the outer periphery of the fixed support column 6, it is possible to prevent the adapter holder 9 from shifting in position in the horizontal direction or coming off. Moreover, since the first engaging portions 16 and the second engaging portions 18 extends over a range exceeding the semicircle of the fixed support column 6 and are attached so as to enclose the fixed support column 6, the detachment does not happen easily.

In addition, in the display device 1 that includes the adapter holder 9 according to the present exemplary embodiment, by mounting the AC adapter 10 that is conventionally placed such as on a desk or on the floor, in the adapter holder 9 that is attached to the fixed support column 6 of the rising and dropping stand 3, it is possible to position and hold it so that it does not get in the way.

Moreover, since the adapter holder 9 that is mounted on the fixed support column 6 by the first engaging portions 16 and the second engaging portions 18a is capable of rotating about the fixed support column 6, it is possible to perform mounting and removal of the adapter holder 9 itself to/from the fixed support column 6 at any desired angular position. Also, when the AC adapter 10 is mounted by positioning the adapter holder 9 that is attached to the fixed support column 6 for example on the side surface or front surface side of the rising and dropping stand 3 with respect to the rising and dropping stand 3, and then rotated to the back surface side of the rising and dropping stand 3 and held there, the freedom of the attachment position and holding position of the AC adapter 10 increases, leading to improved ease of use, and since it is not seen from the front side of the display device 1, the appearance is good.

The present invention is not limited to the aforementioned exemplary embodiment, and suitable modifications can be made without departing from the scope.

For example, in the display device 1 according to the abovementioned exemplary embodiment, the stand is constituted to be able to rise and drop by the fixed support column 6 and the rising and dropping support column 7, but instead of this the stand may consist only of the fixed support column 6 that does not rise or drop.

For that reason, in the state of the adapter holder 9 being mounted on the fixed support column 6, when the AC adapter 10 is mounted, it may not always be possible to be mounted from the front side of the display device 1. Alternatively, if the length of the fixed support column 6 is set comparatively long and a concave portion or groove portion is formed at the midway thereof for placing and engaging the first engaging portions 16, by mounting the AC adapter 10 in the adapter holder 9 from the front side or the lateral side and rotating the adapter holder 9 to the rear surface side, the freedom of the mounting position and holding position of the AC adapter 10 increases and ease of use improves in the same manner as the aforementioned exemplary embodiment.

Also, the aforementioned adapter holder 9 includes first engaging portions that engage from above and second engaging portions that engage on the outer periphery, as attaching portions for attaching and fixing to various stands including the rising and dropping stand 3 or a stand that consists of the fixed support column 6, but it is not always necessary to have two types of engaging portions. For example, either one of the first engaging portions or the second engaging portions may be provided.

The attachment position of the adapter holder 9 to the rising and dropping stand 3 is not limited to the fixed support column 6. For example, it may be attached to the rising and dropping support column 7. In this case, the first engaging portions 16 may be mounted on the rising and dropping support column 7 or the head portion 5. The first engaging portions 16 may be placed at the top surface of the head portion 5, or a concave portion may be formed in the upper end part of the rising and dropping support column 7 and the first engaging portions 16 may be made to engage with that.

### INDUSTRIAL APPLICABILITY

The present invention provides an adapter holder that, by causing a pair of action portions of a mounting portion to undergo resilient deformation with a partition plate serving as a fulcrum, causes first engaging portions and second engaging portions to perform an opening/closing operation whereby mounting to and removal from another member such as a fixed support column is easy, and that in the attached state can be supported in a hanging manner by placing the first engaging portions on the upper end face of the other member, and by keeping the second engaging portions on the outer periphery of the other member in an engaged state to prevent positional shifting, does not easily come off.

Also, in the display device according to the present invention, by mounting an adapter such as an AC adapter, which is conventionally placed such as on a desk or on the floor, in an adapter holder that is attached to a stand, it is possible to position and hold it so that it does not get in the way. Moreover, an adapter holder is provided in which, when the adapter holder is positioned on the side surface or front surface side of the stand, the adapter is mounted therein, and then rotated and positioned at the rear surface side of the stand, the freedom of the mounting position and the holding position of the adapter increases and it is easy to use.

### REFERENCE SYMBOLS

1 Display device
2 Base member
3 Rising and dropping stand
4 Display
6 Fixed support column
6a Upper end face
7 Rising and dropping support column
9 Adapter holder
10 AC adapter
12 Attaching portion
13 Mounting frame
14 Partition surface
15 Supporting portion
16 First engaging portion
18 Concave curved surface
18a Second engaging portion
19 Friction pad
21 Mounting plate
21b Plate portion
22 Bottom portion
22a Concave portion
23 Slit
24 Action portion

1. An adapter holder comprising:
a mounting portion that detachably mounts an adapter; and
an attaching portion that is provided at an opposite side to the mounting portion and is configured to attach to and detach from a separate member,
wherein the attaching portion includes: an engaging portion engaging with the separate member, and a pair of action portions provided at an opposite side to the engaging portion via a partition portion and causing the engaging portion to open and close by resilient deformation with the partition portion serving as a fulcrum, and
the partition portion and the action portions constitute the mounting portion.

2. (canceled)

3. The adapter holder according to claim 1, wherein the engaging portion includes: a first engaging portion provided in a direction approximately perpendicular to a lengthwise direction of the separate member and engaging an upper surface of the separate member; and second engaging portions provided in the lengthwise direction of the separate member and sandwiching the separate member.

4. The adapter holder according to claim 1, wherein the attaching portion includes: a concave curved surface that connects the first engaging portion and the second engaging portions; and a friction pad that is attached to the concave curved surface.

5. The adapter holder according to claim 1, wherein a mounting portion has a bottom part that supports an adapter, and the bottom part has a concave portion through which passes a cord attached to the adapter.

6. A display device comprising:
a stand that is supported by a base member;
a display that is provided at the stand; and
the adapter holder according to claim 1 that is attached to the stand,
wherein the separate member comprises the stand.

7. The display device according to claim 6, wherein
the engaging portion includes: a first engaging portion provided in a direction approximately perpendicular to a lengthwise direction of the stand; and second engaging portions provided in the lengthwise direction of the stand and sandwiching the stand, and
the stand includes a fixed support column, and a rising and dropping support column that is configured to rise and drop with respect to the fixed support column, the first engaging portion of the adapter holder engages an upper end of the fixed support column, and the second engaging portions engage a periphery of the fixed support column.

8. The adapter holder according to claim 3, wherein the attaching portion includes: a concave curved surface that connects the first engaging portion and the second engaging portions and a friction pad that is attached to the concave curved surface.

9. The adapter holder according to claim 3, wherein a mounting portion has a bottom part that supports an adapter, and the bottom part has a concave portion through which passes a cord attached to the adapter.

10. The adapter holder according to claim 4, wherein a mounting portion has a bottom part that supports an adapter, and the bottom part has a concave portion through which passes a cord attached to the adapter.
